(19) United States
(12) Patent Application Publication
(10) Pub. No.: US 2008/0165484 A1
(43) Pub. Date: Jul. 10, 2008

(54) Display tilting apparatus and display rotation apparatus

(75) Inventors: Dong-Won Choi, Suwon-si (KR); Chil-Sung Lee, Suwon-si (KR); Jae-Kyung Kim, Ansan-si (KR); Jae-Hun Kim, Suwon-si (KR); Kyoung-Shin Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,123

(22) Filed: Jan. 7, 2008

(30) Foreign Application Priority Data
Jan. 8, 2007 (KR) 10-2007-0001977

(51) Int. Cl. H05K 7/16

(52) U.S. Cl. 361/681

(57) ABSTRACT

A display tilting apparatus and a display rotation apparatus. The display tilting apparatus, which tiltably supports a display to control an angle of the display, may include: a support member; a tilt member, which is attachable to and detachable from the display, and which is hinge-joined to the support member about a hinge axis; an elastic member, which is joined to the hinge axis, and which applies an elastic force in a direction opposing a gravitational moment of the display; and a driving unit, which is configured to provide a driving force such that the tilt member is tilted. Thus, a display can be moved and rotated without being obstructed by the wall to maintain an optimal viewing angle, while the gravitational moment of the display can be mitigated so that the display can be tilted with a small force, allowing benefits in terms of both space and cost.

### CROSS-REFERENCE TO RELATED APPLICATIONS

This application claims the benefit of Korean Patent Application No. 10-2007-0001977 filed with the Korean Intellectual Property Office on Jan. 8, 2007, the disclosure of which is incorporated herein by reference in its entirety.

### BACKGROUND

1. Technical Field

The present invention relates to a display tilting apparatus and a display rotation apparatus.

2. Description of the Related Art

Flat panel displays, such as TV sets and monitors, employing LCD, PDP, LED technology, etc., provide the benefit of allowing efficient use of small spaces, and are fast replacing Braun tube TV's and monitors. The increase in demand for such flat panel displays is expected to continue into the future. However, due to the thin thicknesses of these flat panel displays, it is difficult to have a flat panel display stand by itself, and thus mounting devices are being developed which allow flat panel displays to be mounted on walls.

The conventional device for mounting a flat panel display on a wall, however, simply affixes the display onto the wall, so that when a user changes one's position, the optimal viewing angle cannot be maintained.

Also, while the wall and the display have to be separated by a certain distance, if the display is to be rotated in a desired direction without being obstructed by the wall, the conventional mounting device provides little or no gap between the display and the wall. This makes it difficult to change the position of the display, and even if an additional member is joined on to separate the display from the wall, the display would protrude outward from the wall because of the additional member. This can undermine the benefits of the flat panel display, of elegant appearance and efficiency in utilizing indoor space, which originate from the characteristic of the flat panel display that it is in close contact with the wall.

Also, when automatically tilting a mass, such as a display, an appropriate power source is required according to the weight of the mass. However, for a large display, the weight of which can be over 40 kg, a large capacity power source may be required for tilting the display, which can impose additional space limitations and increase cost.

Furthermore, there is a need for an apparatus for rotating a display, which makes it possible to select the rotation degree of freedom according to the dimensions of the display and to the environment or requirement of the user.

### SUMMARY

An aspect of the invention is to provide a display tilting apparatus and a display rotation apparatus, which can rotate a display in a desired direction without obstruction by the wall, to maintain an optimal viewing angle.

Another aspect of the invention is to provide a display tilting apparatus and a display rotation apparatus, which can mitigate the gravitational moment of the display, so that the display can be tilted with a small force.

Also, one aspect of the invention is to provide a display tilting apparatus and a display rotation apparatus, which provides a choice in using the tilting function according to the dimensions of the display and the environment or requirement of the user.

One aspect of the invention provides a display tilting apparatus, which tiltably supports a display to control an angle of the display. The display tilting apparatus includes: a support member; a tilt member, which is attachable to and detachable from the display, and which is hinge-joined to the support member about a hinge axis; an elastic member, which is joined to the hinge axis, and which applies an elastic force in a direction opposing a gravitational moment of the display; and a driving unit, which is configured to provide a driving force such that the tilt member is tilted.

For the elastic member, a coil spring can be used that has one end secured to the support member and the other end secured to the hinge axis, with the hinge axis penetrating through the coil spring.

In certain embodiments, the driving unit may include: a first anchorage, which may be joined to either one of the tilt member and the support member, and which may include a motive gear; a second anchorage, which may be joined to the other of the tilt member and the support member; a rack, which may have one end secured to the second anchorage, and which may be in meshing engagement with the motive gear; and a motor unit, which may be configured to provide a rotational force to the motive gear.

In some embodiments, the driving unit may include: a motor, and a gear module, which may be configured to decelerate a rotation speed of the motor, and which includes a main axis, where the main axis of the gear module may be joined to the hinge axis.

Another aspect of the invention provides a display rotation apparatus, which rotatably supports a display to move the display to a predetermined position. The display rotation apparatus includes: a fixed body; a link member, of which one end is hinge-joined to the fixed body; a connector, which is hinge-joined to the other end of the link member; and a display tilting apparatus that is attachable to and detachable from the connector, where the display tilting apparatus includes: a support member joined to the connector; a tilt member, which is attachable to and detachable from the display, and which is hinge-joined to the support member about a hinge axis; an elastic member, which is joined to the hinge axis, and which applies an elastic force in a direction opposing a gravitational moment of the display; and a driving unit, which is configured to provide a driving force such that the tilt member is tilted.

For the elastic member, a coil spring can be used that has one end secured to the support member and the other end secured to the hinge axis, with the hinge axis penetrating through the coil spring.

In certain embodiments, the driving unit may include: a first anchorage, which may be joined to either one of the tilt member and the support member, and which may include a motive gear; a second anchorage, which may be joined to the other of the tilt member and the support member; a rack, which may have one end secured to the second anchorage, and which may be in meshing engagement with the motive gear; and a motor unit, which may be configured to provide a rotational force to the motive gear.

In some embodiments, the driving unit may include: a motor, and a gear module, which may be configured to decelerate a rotation speed of the motor, and which includes a main axis, where the main axis of the gear module may be joined to the hinge axis.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a perspective view of a display tilting apparatus according to an embodiment of the invention.

FIG. 2 is a diagram illustrating the composition of a display tilting apparatus according to an embodiment of the invention.

FIG. 3 is a perspective view of a display rotation apparatus according to an embodiment of the invention.

FIG. 4 is a diagram illustrating the composition of a display rotation apparatus without a display tilting apparatus attached.

FIG. 5 is a diagram illustrating the composition of a display rotation apparatus with a display tilting apparatus attached according to an embodiment of the invention.

FIG. 6 is a perspective view illustrating how a display tilting apparatus according to an embodiment of the invention can be attached for use.

### DETAILED DESCRIPTION

The display tilting apparatus and display rotation apparatus according to certain embodiments of the invention will be described below in more detail with reference to the accompanying drawings. Those components that are the same or are in correspondence are rendered the same reference numeral regardless of the figure number, and redundant explanations are omitted.

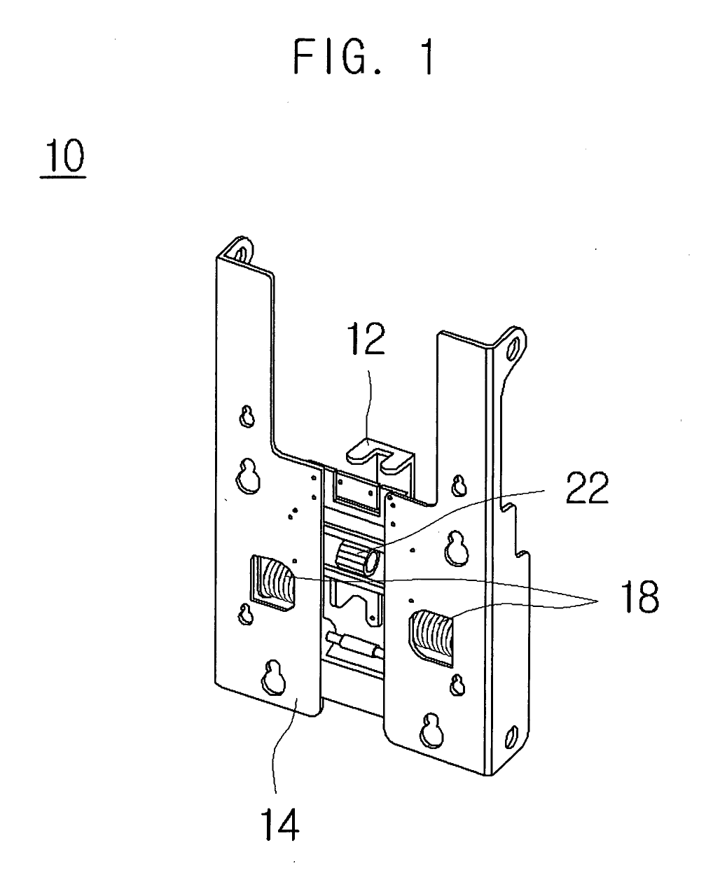

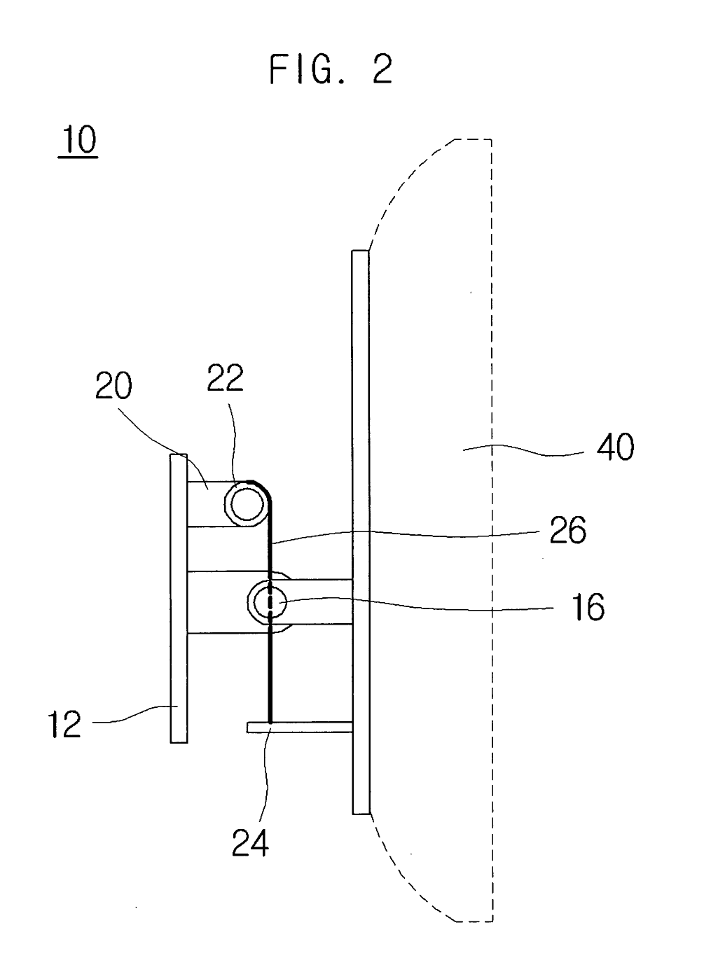

FIG. 1 is a perspective view of a display tilting apparatus according to an embodiment of the invention, and FIG. 2 is a diagram illustrating the composition of a display tilting apparatus according to an embodiment of the invention. In FIG. 1 and FIG. 2, there are illustrated a display tilting apparatus 10, a support member 12, a tilt member 14, a hinge axis 16, elastic members 18, a first anchorage 20, a motive gear 22, a second anchorage 24, and a rack 26.

The display tilting apparatus 10 of this particular embodiment may be composed mainly of a support member 12, a tilt member 14 which is attachable to and detachable from the display and which is hinge-joined to the support member 12 about a hinge axis 16, an elastic member 18 which is joined to the hinge axis 16 and which applies an elastic force in a direction opposing the gravitational moment of the display, and a driving unit configured to provide a driving force that tilts the tilt member 14. This display tilting apparatus 10 can tiltably support a display to control the upward/downward angle of the display.

The support member 12 can be the element that secures the tilting apparatus 10 to a particular position, while the tilt member 14 can be the element to which the display is joined, such that rotating the tilt member 14 may control the upward/downward rotation angle of the display. The tilt member 14 may be such that allows the attaching/detaching of a display, so that displays of various sizes can be joined.

The tilt member 14 may be hinge-joined to the support member 12 about the hinge axis 16, such that the upward/downward rotation angle of the display can be controlled.

The elastic members 18 may be joined to the hinge axis 16 and may apply elastic forces in a direction opposing the gravitational moment of the display, to mitigate the moment caused by the weight of the display, so that the display may be tilted with a power source of a small capacity. A large-sized display can weigh as much as 40 kg or more, and can generally require a power source of a high capacity, but by using the elastic forces of the elastic members, the moment caused by the weight of the display can be mitigated.

To lessen the load of a heavy display, the position of the hinge axis 16 can be made lower than the center of mass of the display, such that the elastic members 18 may support the display with a minimal amount of elastic force while making it possible to tilt the display with a power source of a small capacity.

In this particular embodiment, two coil springs may be used for the elastic members 18. The two coil springs may be inserted onto either end of the hinge axis 16. For each coil spring, one end of the coil spring may be secured to the support member 12, a torsion may be rendered in the coil spring in a direction opposing the gravitational moment of the display, and the other end of the coil spring may be secured to the hinge axis, so that the coil spring may apply an elastic force.

The driving unit may provide a driving force that tilts the tilt member 14, to which the display is joined. The driving unit of this embodiment may include a first anchorage 20 which can be joined to one of the tilt member 14 and the support member 12 and which has a motive gear 22, a second anchorage 24 which can be joined to the other of the tilt member 14 and the support member 12, a rack 26 having one end secured to the second anchorage 24 that is in meshing engagement with the motive gear 22, and a motor unit configured to provide a rotational force to the motive gear 22.

The first anchorage 20 having the motive gear 22 may be joined to a surface of the support member 12 facing the tilt member 14, with the second anchorage 24 placed on a surface of the tilt member 14 facing the support member 12. Of course, it is possible to join the first anchorage 20 to the tilt member 14 and the second anchorage 24 to the support member 12.

The rack 26 may mesh with the motive gear 22, to convert the rotational movement of the motive gear 22 into a linear movement and thus tilt the tilt member 14. One end of the rack 26 can be secured to the second anchorage 24, and the rack 26 may be in meshing engagement with the motive gear 22. As such, the rack 26 can be utilized to control the distance between the first anchorage 20 and second anchorage 24, according to the forward and reverse rotation of the motive gear 22, thereby allowing the tilt member 14 to be tilted about the hinge axis 16.

The motor unit (not shown) may include a motor, and a gear module that decelerates the rotation speed of the motor. The motor unit may provide a rotational force to the motive gear 22, to forwardly and reversely rotate the motive gear 22, causing the rack 26 to move linearly. The linear movement of the rack 26 may control the distance between the first anchorage 20 and the second anchorage 24, whereby the tilt member 14 may rotate about the hinge axis 16 relative to the support member 12. A worm gear module, including a worm and a worm gear, may be joined as necessary to the main axis of the gear module, to further decelerate the rotation speed of the motor and prevent the display from shaking due to backlash in the gear module.

The method of operating a display tilting apparatus 10 according to this embodiment will now be described below with reference to FIG. 2.

The hinge axis 16 can be positioned lower than the center of mass of the display, and coil springs can be disposed on the hinge axis 16 against the moment created by the mass of the display, such that when the display is attached to the tilt member 14, the display may not rotate downwards. In this state, the display can be tilted upwards or downwards even when a power source of a low capacity is used.

When the motive gear 22 equipped on the first anchorage 20 is rotated by the driving of the motor unit, the meshed rack 26 may move in an upward or downward direction. That is, the rack 26 may move upwards or downwards according to the forward or reverse rotation of the motor, and since one end of the rack 26 may be secured to the second anchorage 24, the distance of the first anchorage 20 to the second anchorage 24 can be controlled. The tilt member 14, to which the first anchorage 20 is secured, can be tilted in an upward or downward direction according to the distance between the first anchorage 20 and second anchorage 24.

Alternately, the driving unit may include a motor, and a gear module which decelerates the rotation speed of the motor and which includes a main axis, where the main axis of the gear module may be joined to the hinge axis 16. That is, if the tilt member 14 is secured to the hinge axis 16, and the hinge axis 16 is rotatably joined to the support member 12, the tilt member 14 secured to the hinge axis 16 may be rotated in an upward or downward direction by rotating the hinge axis 16 directly.

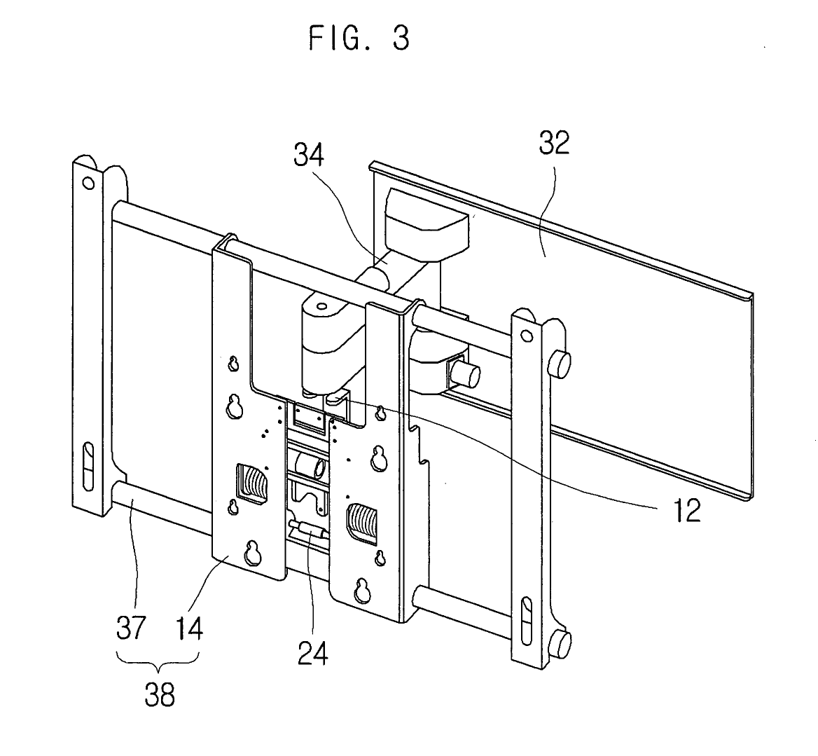

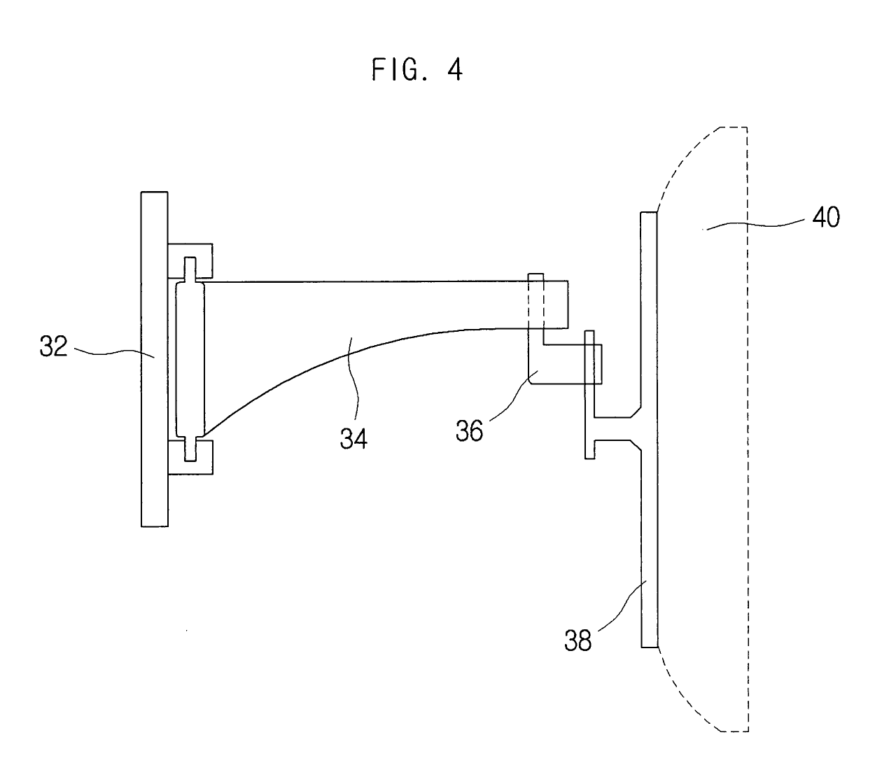

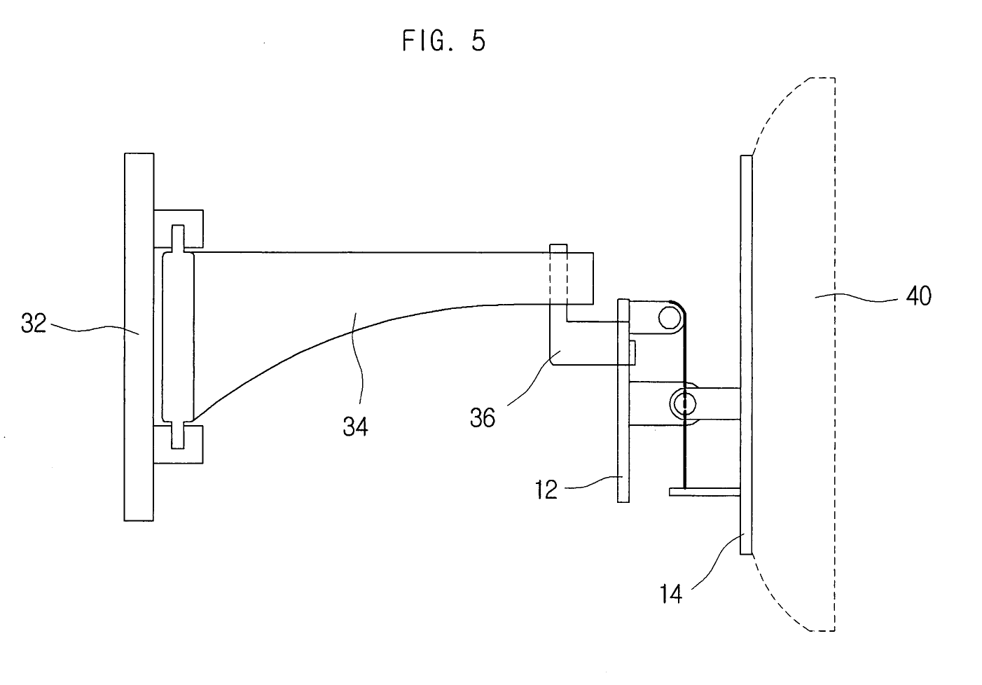

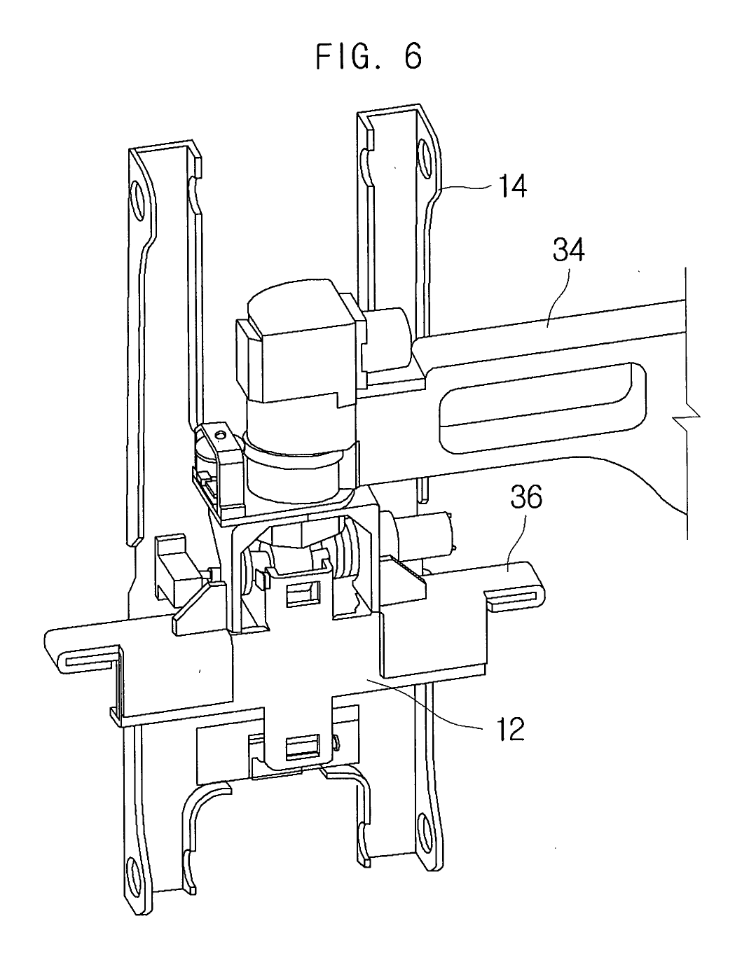

FIG. 3 is a perspective view of a display rotation apparatus according to an embodiment of the invention, FIG. 4 is a diagram illustrating the composition of a display rotation apparatus without a display tilting apparatus attached, and FIG. 5 is a diagram illustrating the composition of a display rotation apparatus with a display tilting apparatus attached according to an embodiment of the invention. FIG. 6 illustrates how a display tilting apparatus according to an embodiment of the invention can be attached for use. In FIG. 3 to FIG. 6, there are illustrated a fixed body 32, a link member 34, a connector 36, a guide frame 37, a movable body 38, a display 40, a display tilting apparatus 10, a tilt member 14, and a support member 12.

The display rotation apparatus of this embodiment may be composed mainly of a fixed body 32, a link member 34 having one end hinge-joined to the fixed body 32, a connector 36 hinge-joined to the other end of the link member 34, and a display tilting apparatus 10 that can be attached to and detached from the connector. This display rotation apparatus can rotatably support a display 40 to move the display 40 to a particular position.

The axes of rotation for the hinge-joint portions at both ends of the link member 34 may be substantially parallel to each other, and may be substantially perpendicular to the hinge axis 16 of the tilting apparatus 10. This not only allows translational movement of the movable body 38 with respect to the fixed body 32, but also allows rotation of the movable body 38 in the left, right, upward, and downward directions.

In the display rotation apparatus of this particular embodiment, the fixed body 32 may be secured to a wall, and a display 40, such as an LCD and PDP, etc., may be secured to the movable body 38. In this way, the movable body 38 can be moved in a translational manner or rotated in the left, right, upward, and downward directions, such that the front of the display 40 faces a direction desired by the user.

The movable body 38 is meant to encompass the tilt member 14 of the display tilting apparatus 10, and can be made to correspond to the dimensions of the display 40 by joining a guide frame 37 to the tilt member 14. That is, not only can the display be supported solely by the tilt member 14, but also, if a large-sized display 40 is to be joined, a guide frame 37 can be joined to the tilt member 14 to support the large display 40.

The support member 12 of the display tilting apparatus 10 may be secured to the connector 36, whereby the tilt member 14 may rotate upwards or downwards about the hinge axis 16 relative to the support member 12.

Looking at the method of operating a rotation apparatus according to this embodiment, the link member 34 may be rotated about the fixed body 32, due to the hinge joint between one end of the link member 34 and the fixed body 32, and thus the movable body 38 joined to the other end of the link member 34 can move in a translational movement relative to the fixed body 32. Also, the hinge joint between the other end of the link member 34 and the connector 36 allows the movable body 38 to be rotated left and right, while the display tilting apparatus 10 detachably joined to the connector 36 allows the movable body 38 to be rotated upwards and downwards.

The display tilting apparatus 10 can be attached to or detached from the display rotation apparatus according to the dimensions of the display 40 and the environment or requirements of the consumer. If the user does not wish to use the tilting function for the display 40, the manufacturer can provide a rotation apparatus without the tilting function, in which case the display rotation apparatus may offer only the translational movement and left/right rotation functions. If the user does wish to use the tilting function, the display tilting apparatus 10 can be provided with the rotation apparatus attached, to accommodate the preferences of the user.

FIG. 4 illustrates a display rotation apparatus that does not have a tilting function. Referring to FIG. 4, the movable body 38 may be secured to the connector 36, and the link member 34 may be rotated about the fixed body 32, due to the hinge joint between one end of the link member 34 and the fixed body 32, and thus the movable body 38 joined to the other end of the link member 34 can move in a translational movement relative to the fixed body 32. Also, the hinge joint between the other end of the link member 34 and the connector 36 allows the movable body 38 to be rotated left and right.

FIG. 5 illustrates a display rotation apparatus that has a display tilting apparatus 10 attached, to provide a tilting function. Referring to FIG. 5, the support member 12 of the display tilting apparatus 10 may be secured to the connector 36, and as the tilt member 14 may rotate about the hinge axis 16 relative to the support member 12, the display may rotate up and down.

The description for each component of the display tilting apparatus 10 may be substantially the same as that presented above, and thus will not be repeated.

By utilizing certain embodiments of the invention as set forth above, a display can be moved and rotated without being obstructed by the wall to maintain an optimal viewing angle, while the gravitational moment of the display can be mitigated so that the display can be tilted with a small force, allowing benefits in terms of both space and cost.

Also, a display tilting apparatus can be made attachable to and detachable from the display rotation apparatus, which provides the consumer with a choice in whether or not to use the tilting function, according to the dimensions of the display and the environment or requirement of the user.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A display tilting apparatus tiltably supporting a display and configured to control an angle of the display, the display tilting apparatus comprising:
a support member;
a tilt member attachable to and detachable from the display and hinge-joined to the support member about a hinge axis;
an elastic member joined to the hinge axis and configured to apply an elastic force in a direction opposing a gravitational moment of the display; and
a driving unit configured to provide a driving force such that the tilt member is tilted.

2. The display tilting apparatus of claim 1, wherein the elastic member is a coil spring having one end thereof secured to the support member and the other end thereof secured to the hinge axis,
and wherein the hinge axis penetrates through the coil spring.

3. The display tilting apparatus of claim 1, wherein the driving unit comprises:
a first anchorage joined to one of the tilt member and the support member, the first anchorage having a motive gear;
a second anchorage joined to the other of the tilt member and the support member;
a rack having one end thereof secured to the second anchorage, the rack in meshing engagement with the motive gear; and
a motor unit configured to provide a rotational force to the motive gear.

4. The display tilting apparatus of claim 1, wherein the driving unit comprises:
a motor; and
a gear module configured to decelerate a rotation speed of the motor, the gear module comprising a main axis,
and wherein the main axis of the gear module is joined to the hinge axis.

5. A display rotation apparatus rotatably supporting a display and configured to move the display to a predetermined position, the display rotation apparatus comprising:
a fixed body;
a link member having one end thereof hinge-joined to the fixed body;
a connector hinge-joined to the other end of the link member; and
a display tilting apparatus attachable to and detachable from the connector,
wherein the display tilting apparatus comprises:
a support member joined to the connector;
a tilt member attachable to and detachable from the display and hinge-joined to the support member about a hinge axis;
an elastic member joined to the hinge axis and configured to apply an elastic force in a direction opposing a gravitational moment of the display; and
a driving unit configured to provide a driving force such that the tilt member is tilted.

6. The display rotation apparatus of claim 5, wherein the elastic member is a coil spring having one end thereof secured to the support member and the other end thereof secured to the hinge axis,
and wherein the hinge axis penetrates through the coil spring.

7. The display rotation apparatus of claim 5, wherein the driving unit comprises:
a first anchorage joined to one of the tilt member and the support member, the first anchorage having a motive gear;
a second anchorage joined to the other of the tilt member and the support member;
a rack having one end thereof secured to the second anchorage, the rack in meshing engagement with the motive gear; and
a motor unit configured to provide a rotational force to the motive gear.

8. The display rotation apparatus of claim 5, wherein the driving unit comprises:
a motor; and
a gear module configured to decelerate a rotation speed of the motor, the gear module comprising a main axis,
and wherein the main axis of the gear module is joined to the hinge axis.
